(19) United States
(12) Patent Application Publication
(10) Pub. No.: US 2013/0189489 A1
(43) Pub. Date: Jul. 25, 2013

(54) MICRO-RELIEF STRUCTURES

(71) Applicants: Igor Jermolajev, Rez-Husinee (CZ); Libor Kotacka, Rez-Husinee (CZ); Tomas Tethal, Rez-Husinee (CZ); Robert Dvorak, Praha 6 (CZ)

(72) Inventors: Igor Jermolajev, Rez-Husinee (CZ); Libor Kotacka, Rez-Husinee (CZ); Tomas Tethal, Rez-Husinee (CZ); Robert Dvorak, Praha 6 (CZ)

(73) Assignee: Optaglio S.R.O., Rez-Husinec (CZ)

(21) Appl. No.: 13/147,328

(22) PCT Filed: Feb. 8, 2010
(86) PCT No.: PCT/EP2010/051521

§ 371 Date: Sep. 18, 2012

(30) Foreign Application Priority Data
Feb. 9, 2009 (GB) 0902000.9

(51) Int. Cl. B42D 15/00; B05D 5/06; H05K 3/00; B05D 5/00

(52) U.S. Cl. CPC B42D 15/00; B05D 5/00; B05D 5/06; H05K 3/00
USPC 428/161; 428/172; 427/258; 427/162; 427/96.2

(57) ABSTRACT

The present invention provides a method of forming a relief pattern as part of a layered structure and comprising, forming a relief pattern on the surface of a layer of the said structure and subsequently forming a protective fixing layer on at least part of the said relief pattern and serving to protect the underlying relief pattern during any subsequent processing of the said structure, and thereby also provides for a layered structure, generally comprising a substrate having a relief pattern formed on a surface of the substrate and wherein at least a portion of the said relief has been provided with a protective fixing layer serving to retain the characteristics of the relief pattern during any subsequent processing of the structure such as, for example, when forming a laminate structure with the relief pattern provided therein.

The present invention relates to micro-relief structures, and structures employing embedded thin film structures, and to methods of producing the same.

There are many techniques of embossing micro- or even nano-scaled relief into various materials. There is however a frequent problem of maintaining the relief when further processed either mechanically (embossed, squeezed) or, for example, when laminated under a relatively high temperature, especially in case of thermoplastic materials, when the relief is essentially perturbed or totally erased or when there is a danger that the relief pattern might in same way be damaged.

It has been historically a problem to have a diffractive relief embedded inside materials like polycarbonates etc., as any known lamination technique would lead to an absolute erasure of the diffractive or similar micro-relief, either due to diffractive indices matching or due to mechanical and/or thermoplastic abolishment of the relief.

In situations where the security holographic information is embedded or buried in a thermoplastic body, any perturbation of the material may allow the metal element to be easily removed from the plastics and subsequently reused in counterfeited security device or related tool.

The present invention therefore seeks to provide a solution to such problems in which any counterfeit, or disassembly, attempt could lead to non-reversible disintegration of the original forensic feature.

The invention relates to a deposition of a relatively thin metallic, or non-metallic, film on a material that can receive for example a micro-relief pattern, for example such as a thermoplastic material with a microrelief embossed on the surface and subsequent fixation of the relief. This may be followed by the provision of a protective layer which, again, could comprise a thermoplastic material, or for example a silicon-based material. It should be appreciated also that this further layer could likewise comprise an over-painted, or over-deposited, layer exhibiting appropriate adhesion between the various materials. Lamination with another film is also another likely possibility. The presence of such a thin layer on the relief essentially changes its mechanical properties.

Also, the required elements/features could be entirely buried within the body of the structure or could simply be arranged to comprise the outermost surface thereof and whether or not including any further protective layer.

This means that the relief can be advantageously fixed through the thin film for further applications and technological steps, where the thermoplastic material is exposed to higher temperature even reaching or exceeding a melting point, when the microrelief itself would disappear or be seriously modified or somehow disturbed. This can advantageously be used in further exploitation of the microrelief, e.g. for security devices. Thus, in a further production step, the embossed material can be laminated with another thermoplastic film in such way that certain portions of the relief where no fixation of the relief is present would loose any information about the original microrelief, whilst the sections of being fixed via the approach described in the invention is preserved after the lamination. This can be generally used for such tasks when a certain material (e.g. metal platelets) carrying a diffractive motif is to be located inside another one, mostly buried in a thermoplastic body. This invention also relates to the manufacture and composition of articles containing a new security device, i.e. when the embedded thin film foil-like discrete elements bear a holographic and spatial information. Further, the elements are spatially organized and distributed in such a way, that can be read or detected by means of the electromagnetic radiation, or the parts of the foil are arranged in such a way, that can be detected by means of the optical tomography or a radar assisted technique, for example.

It will therefore be appreciated that according to one aspect of the present invention there is provided a method of fixing a micro-relief structure such as for example a diffractive and/or holographic structure, to be formed in relation to the substrate body and through the provision of a protective layer/film material over the structure. Advantageously, the protective layer/film has no or only limited, effect on the optical properties of the relief structure. In particular, the substrate can comprise a thermoplastic material and the protective layer/film can comprise a metallic layer of film advantageously grown on the relief structure of the substrate material.

Advantageously, the invention can allow for the provision of a selectively located fixing layer which can, for example, comprise a grown layer or a demetallised layer, and which serves to fix the relief pattern in its required form an offer subsequent protection particularly during possible further processing steps.

The invention also provides for a method of forming a thin fixing-layer structure, such as for example a thin metallic film/layer structure, or an organic or inorganic material layer, within a bulk body and comprising the selective deposition of the metal layer/film, in a patterned manner if required, upon an intermediate exposed surface of the bulk body and prior to further processing with a second layer of the bulk body. Advantageously, the further process comprises lamination and, in particular, further processing can serve to unify the two portions of the bulk body into a unitary member with the metallic layer/film eventually buried and/or embedded therein.

Advantageously, the metallic layer/film can be formed in association with, or on a relief structure of the bulk substrate body and in a manner as defined above.

It will be appreciated that the provision of, for example, the metallised layer/film over the relief structure can serve to not only protect the relief structure due in further processing/lamination of the substrate but likewise serves to lead to selective provision of a patent diffractive structure insofar as the further processing/lamination of the substrate is specifically designed to allow for destruction of regions of the relief structure not so protective.

The method also provides for the provision of a visibly discernable motif and/or graphical character and comprising a plurality of spatially located embedded layer/film segments and exhibiting a predefined spatial location which can be interrogated through the application of appropriate radiation. Each of said layer/film elements can advantageously be formed in accordance with the further steps such as those noted above.

Of course it should also be appreciated that the invention can provide for a combination of any of the processing steps and of course to the provision of structures such as those formed in accordance with such methods and wherein the layer/film structures can be such as those discussed above.

Firstly, the metallic film, or any other appropriate non-nonmetallic material, has to be applied, and as a further example, metal elements can be grown but not removed from the surface as in WO 2005/078530. They can remain the surface and would cause the fixation of the relief. The galvanized layer may thus be essentially thinner than previously known as the metallic body is not necessarily self-supporting (self-standing). It should be just as thin as needed to copy the relief. Of course thicker elements are useful as well. However, the provision of a particularly thin layer also leads to further advantageous effects and features. For example, with a relatively thick layer, i.e. one having a height that is somewhat greater than the height of the relief pattern of the structure, the required relief pattern will be accurately copied on one side of the interface, however, the opposite side of the layer will not bear any such details of the relief pattern and will appear substantially flat. If, however, the thickness of the deposited layer is compatible with the height/depth of the relief, that is, for example, not more than two or three times the depth, the relief can be replicated on both sides of the deposited layer such that both interfaces offered by the layer with them replicated the relief structure.

Also, there is the possibility to provide for a deposition by another technique other than the galvanoplastic one described above, and which, for example, could comprise and “overprint” step, the embossed relief with a color, with a nonmetallic layer. This can be achieved in such a way that the plain substrate is covered by a layer, subsequently being embossed. A color helps to further metallization.

All such steps are preferably done towards a further lamination, where the hologram (embossed surface) situated in the interface when two thermoplastic bodies being instantly attached.

The invention advantageously employs controlled deposition of the layer in order to fix, or to maintain the relief when further processed. This can be done either through direct deposition on top of the embossed surface, the layer would copy the relief. Another way is to deposit a specialty layer, being then embossed and further processed. Of course, any appropriate masking technique, with a recess being exposed and developed, or any appropriate printing technique properly defining the required shield (14) and the borders thereof can be provided.

The invention deals with a way of presenting the relief. In other case the relief will be definitely lost, either melted during the lamination, or there will be no refractive index contrast, so the relief would have zero optical properties. The invention also relates to the controlled distribution of the layer can thus be as thin as few tens of nm, what is new regarding the application mentioned above. The layer is advantageously just thick enough to “freeze” the relief of to exhibit some optical properties change.

The invention is described further hereinafter, by way of example only, with reference to the accompanying drawings in which:

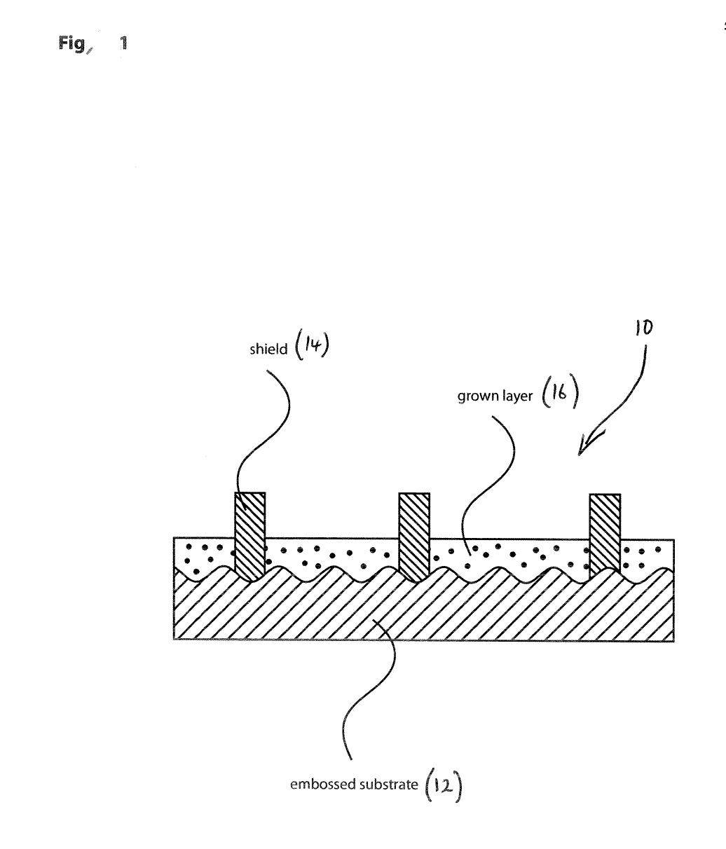

FIG. 1 is a schematic cross section through an embossed substrate for forming a structure according to an embodiment of the present invention;

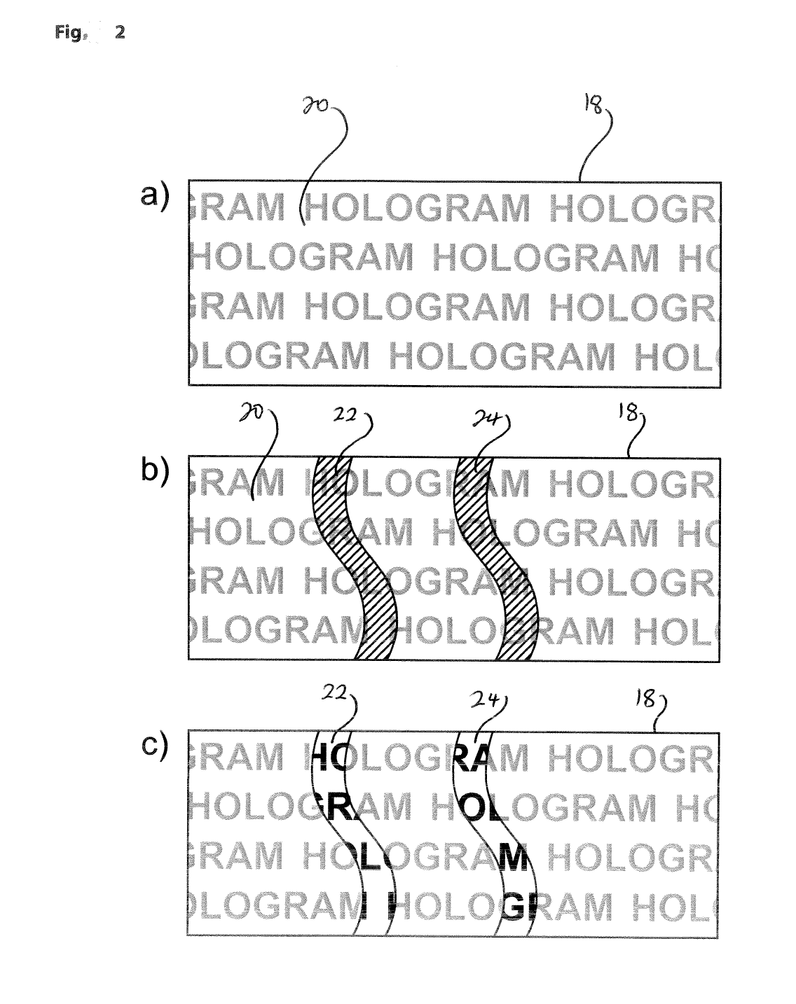

FIG. 2a-2c are schematic plan views of a substrate such as that of FIG. 1 and illustrating different processing steps of an embodiment of the invention;

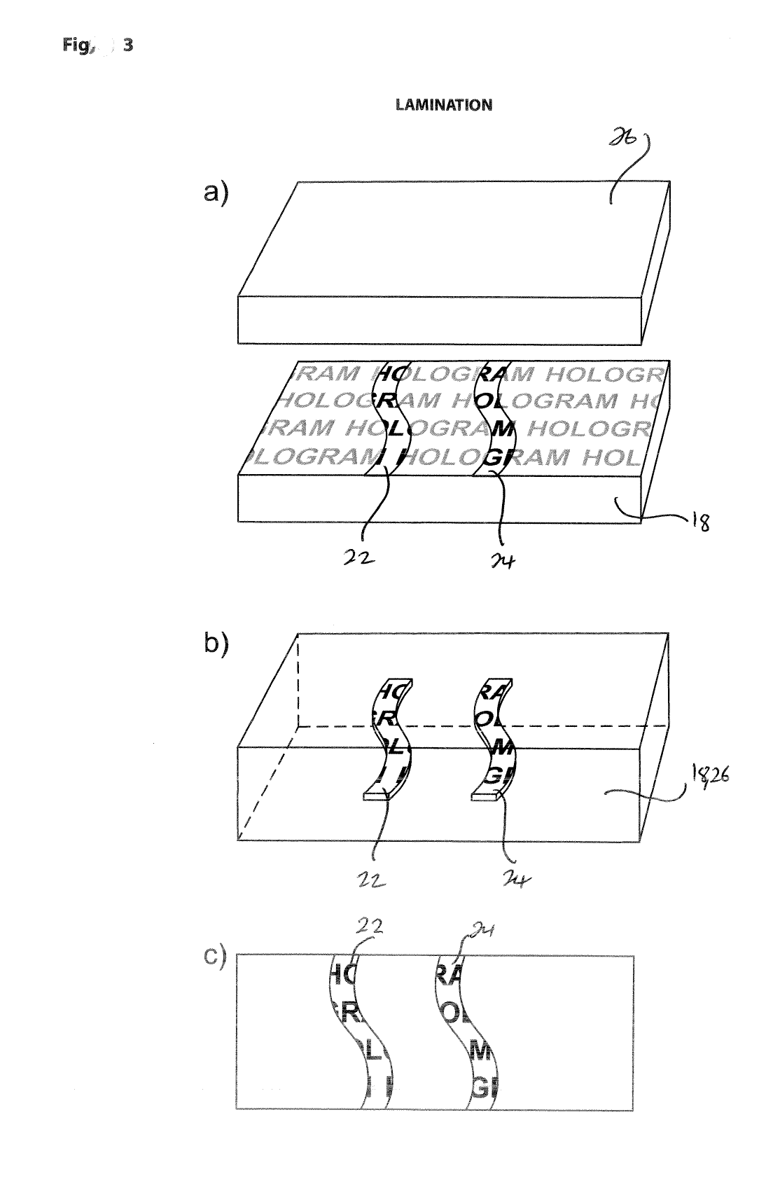

FIG. 3a-3c illustrates further process steps of the structure of FIG. 2a-2c;

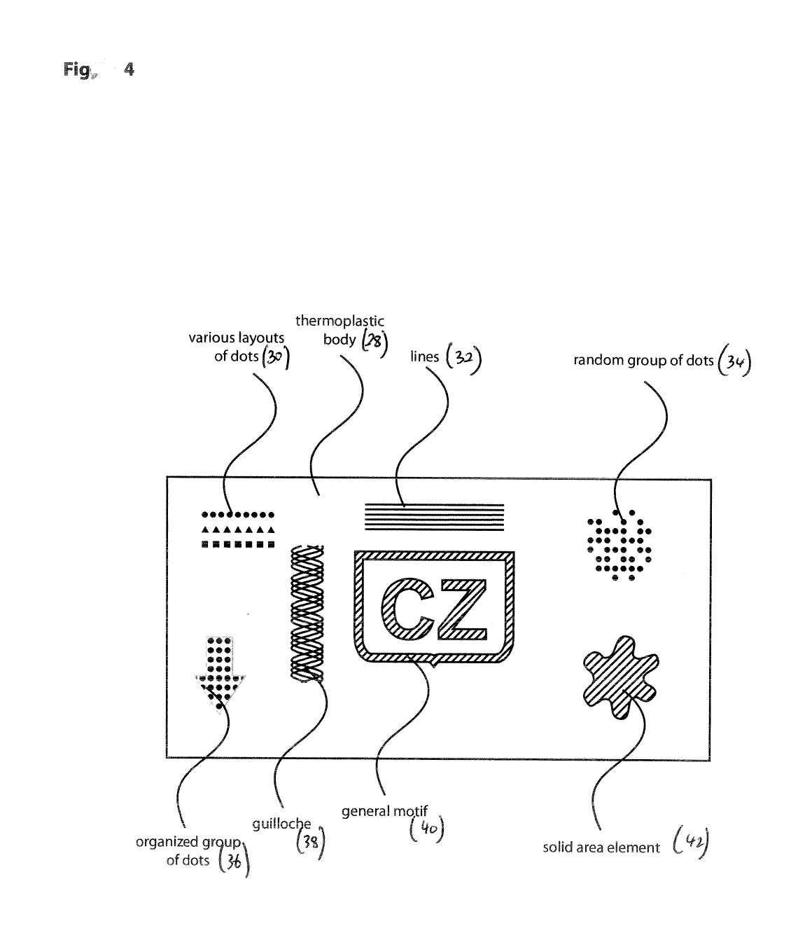

FIG. 4 is a plan view of the substrate illustrating different forms of shapes and graphical motifs that can be provided within a substrate in accordance with an embodiment of the present invention;

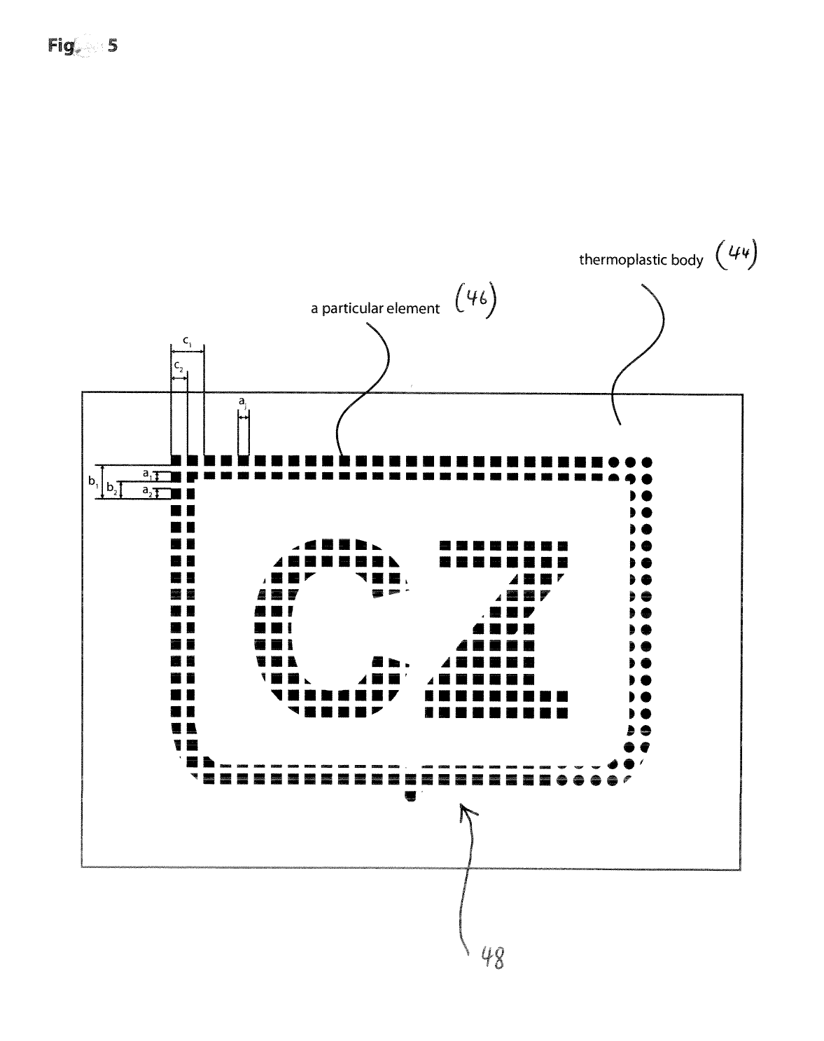

FIG. 5 shows in greater detail one of the motifs illustrated in FIG. 4;

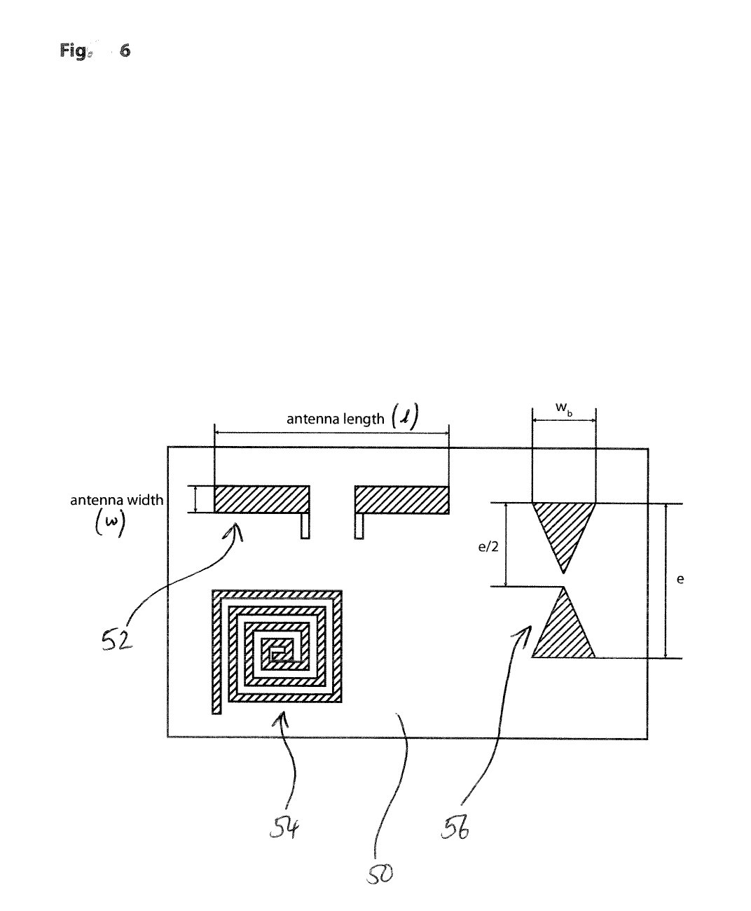

FIG. 6 illustrates a variety of forms of antennae configurations accordingly to an embodiment of the present invention;

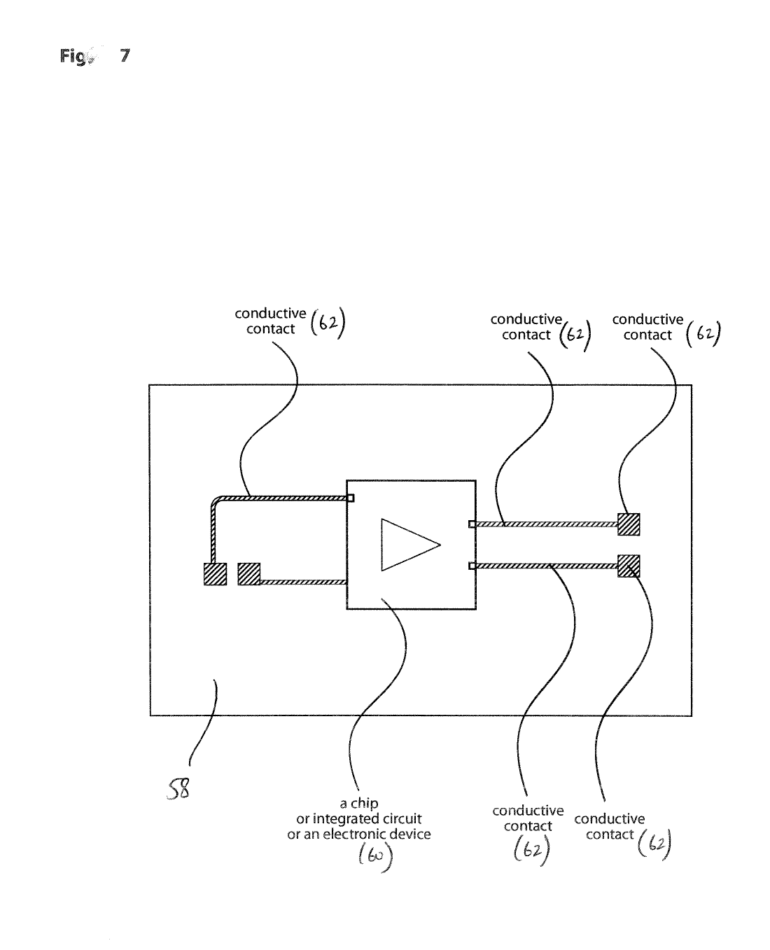

FIG. 7 illustrates the examples of different patterns formed within the substrate in accordance within the present invention; and

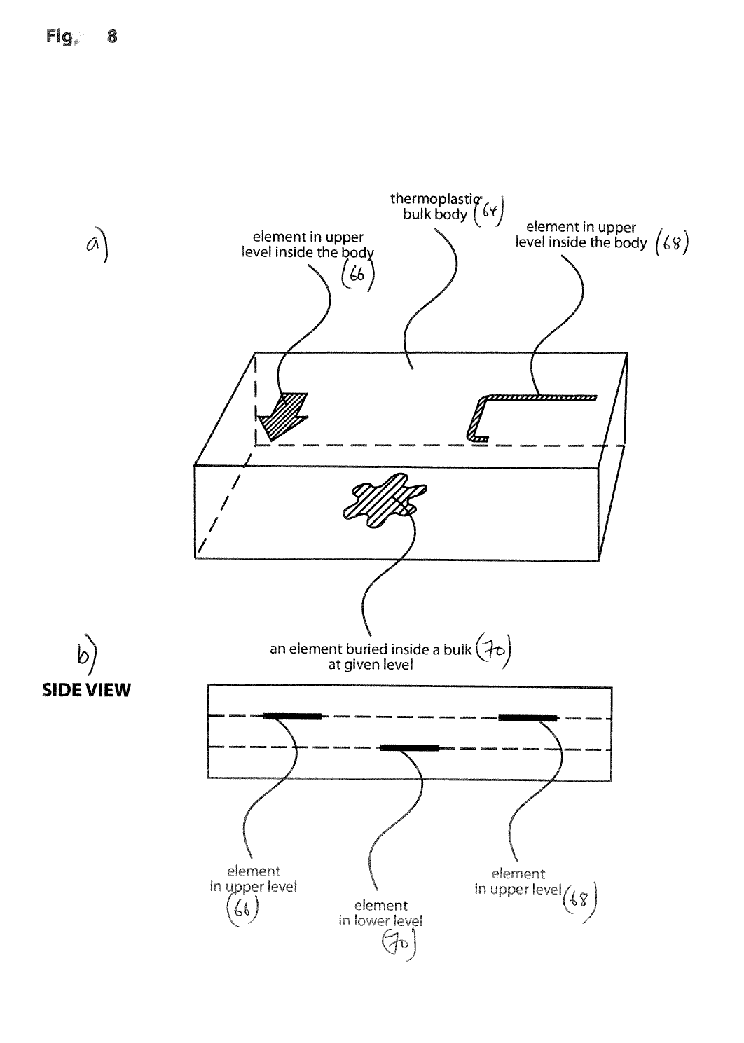

FIG. 8a and 8b show the formation of brief elements at different levels/positions within a substrate according to an embodiment of the present invention.

As will be appreciated, one particular aspect of the present invention relates to the provision of a “fixed” micro relief structure that can readily be provided in a discrete and isolated manner, within the body of a, for example, thermoplastic substrate.

In an example of the invention such as that of the illustrated embodiment, it will be appreciated that the substrate is provided preferably consisting of at least one substrate layer, for example a thermoplastic layer, or any other appropriate material such as PET, and wherein a micro-, or nano-relief structure is embossed and subsequently covered with

an ultra thin conductive film/layer. The layer can be formed continuously covering the surface of the thermoplastic substrate or, alternatively, can be arranged to remain/cover

only selected portions of substrate such as in a patterned manner or otherwise. The ultra thin conductive layer is substantially thinner than the height of the relief and therefore offers minimum influence over the optical, diffractive and/or mechanical properties of the relief.

An example of the initial stages in the formation of such a structure is illustrated with regard to FIG. 1. Here a layered structure 10 is illustrated comprising an embossed substrate 12 comprising a thermo plastic substrate 12 having an embossed micro or nano relief pattern formed thereon prior to, as an example, the selected formation of a electro-insulating material shield 14.

Subsequent to the location of the shield 14, the embossed substrate 12, and its relief pattern, is galvanized in the regions not covered by the shield 14 and so as to form a grown layer 16, comprising an ultra thin metal film in the illustrated example and which serves to “fix” the holographic relief offered by the relief pattern on the underlying substrate 12. As examples, the effects of metal layer/film 16 can be from a few nm to a few mm. It should be appreciated that an alternative process would be to print or otherwise deposit some for of dielectric material on top of the surface of the substrate prior to embossing. A specific colour could be chosen whether for the layer 16 of FIG. 1, or whether as part of a printed dielectric and, if the latter, the layer/film can be subsequently patterned due to an appropriate photographic-type technique in order to yield the desired surface pattern.

Turning now to FIGS. 2a-2c, a schematic view of a further substrate 18 is provided accordingly to an embodiment of the present invention and upon which a holographic diffractive relief plan 20 is formed as illustrated in FIG. 2a. The holographic relief pattern in this example is embossed on the surface of the substrate 18. The upper surface bearing the relief pattern 20 is then itself patterned, either directly by printing or through a lithographic/masking type process or in accordance with the example illustrated in FIG. 1 such that patterned overlying metal films 22, 24 are then provided on the relief of the substrate 18 and at the pre selected locations.

As discussed previously, the introduction of the patterned metal films 22, 24 to the relief structure 20 serves to “fix” the relief structure of the underlying substrate 18 in the portions beneath the patterns 22, 24. In this manner, the relief pattern within the portions 22, 24 is actually provided by way of the metal film which, as noted, while fixing the relief structure, offer a generally very limited influence on the optical/physical characteristics of the relief structure and as illustrated further in FIG. 2c.

The substrate 18 FIG. 2c with its selectively “fixed” regions 22, 24 of micro structure can then be further processed, for example, by way of an additional step of lamination. Such a further laminated step is illustrated in FIGS. 3a-3b. Turning first to FIG. 3a, the substrate 18 with the embossed, now metallised hologram areas 22, 24 is covered with a further layer of thermoplastic material 26 as illustrated in FIG. 3a. Of course, it should be appreciated that, in addition to providing the fixing layer through for example a metallisation and/or covering/deposition procedure, the required layer can be provided in an inverse manner, that is through a selective de-metallisation, or other material-removal, procedure in order to arrive at a required pattern of fixing element.

After, for example, a standard lamination process, the two thermoplastic elements, i.e. the additional layer 26 and the substrate 18 become a single bulk body 18, 26 as illustrated in FIG. 3b and with the metallised relief patterns 22, 24 encased within that combined body 18, 26. Again, it should of course be appreciated that, as an alternative to such standard lamination techniques, the invention envisages any appropriate adhesive-assisted technique, and techniques involving the fusing of layers, for providing the required structure.

The holographic relief patterns found within the thermoplastic substrate 18 not covered by the metal 22, 24 is perturbed, and generally totally disappears, by virtue of the further laminating process-particularly since the relief pattern in those areas has not been fixed by the addition of the metal film as indeed, the case at locations 22, 24.

A top view of the combined laminating body is illustrated at FIG. 3c from which the stripes 22, 24 are clearly visible and which carry holographic information of the original micro structure of the substrate 18.

It will of course be appreciated that various patterning techniques can be employed so as to form a wide variety of various shapes and graphical motifs in accordance with the present invention. Also, the invention is not limited to the “S” stripes such as illustrated in FIGS. 2 and 3. Rather, a thermoplastic body 28 can be provided with a wide variety of shapes and motifs' such as the series dots 30, lines 32, random dots 34, or organised dots 36, guilloche pattern 38, with a general motif 40 and solid area element 42 illustrated in FIG. 4.

Turning now to FIG. 5, there is provided an illustration of one of the possible patterns comprising the general motif 40 of FIG. 4 and which, as confirmed by the details of FIG. 5, is formed from a patterned array of small dots/elements 46. The coordinate position and dimensions of each of the dots such as illustrated by a₁, a₂, a₁; b₁, b₂, and c₁, C₂ can be employed to not only combined to provide a readily identifiable visual indication of the motif but can, through their predefined spatial orientation, serve to provide a configuration of such dots/elements 46 that can be readily detectable through use of electromagnetic wave interrogation, for example radar-assisted techniques through observing a diffractive pattern of the structure. Of course, the characteristic size of each particular element, as well as the spacing between such elements, can be varied, and to some extent be dependent upon, the actual technique employed for the graphical termination of the elements.

As an example, the use of standard optical lithographic and masking techniques, as well as printing techniques, allows for precision in the order of the few microns, and features in the region of 1 μm could be provided. Indeed through the use of advanced optical lithographic techniques, generally UV assisted, or even electron beam writing techniques, can offer potential depiction of details of the element has small as 100 nm. In this manner, the particular details of the relief structure could be of a size compatible with the characteristic size of the release itself.

As will be appreciated, through an appropriate chosen spacing between the various elements, additional laser-assisted writing and/or laser-personalisation of for example identification documents can be readily achieved. Yet further, the density at which such elements are employed serves to control the transparency of the structure and, since each element can readily be provided at dimensions generally smaller than are observable with the naked eye, even a structure employing metallic elements can exhibit a semi-transparent appearance.

The provision of a motif in this manner can prove particularly advantageous insofar as any attempt to release the motif from the substrate body, for potential further use in a counterfeiting manner, will lead to distortion of the spatial relationship between the various elements which will be readily discernable during subsequent investigation by way of electromagnetic waves and some form of radar-assisted techniques. Thus, even if the distortion of the motif 48 is not readily discernable by the naked eye, further investigation relying upon the spatial relationship between the various elements will indicate that some form of distortion has occurred thereby indicating an attempt to misuse the security label/structure bearing the motif.

Of course, it will be appreciated that the metallised structures embedded within a substrate according to the present invention, can themselves comprise electronic components and FIG. 6, illustrates the substrate 50 having metallised portions forming a dipole antenna 52 with width w and length 1, and an inductor-type antenna 54 and a butterfly antenna 56 having the triangular half loops with the respective dimensions e, W_{b} and _{e/2} as indicated. The sizes of the particular elements that can be achieved by way of this technique offer advantageous features insofar as a variety of rudimentary electronic elements working within a broad spectrum of frequencies, for example up to THz can be provided. For sizes of elements in the order of 1 um, or even smaller, the methods embodying the present invention allows for the production of ices from the category of so called photonic devices and meta-material devices.

Yet further, such elements can also be formed of comfort to the appropriate semiconductor or dielectric materials so as to assist in the incorporation of printed-electronics features within the overall structure.

FIG. 7 shows another arrangement in which the embedded metallised portions within a substrate 58 having an integrated circuit or electronic device 60 therein and comprising conductive contacts 62 therefor. The provision for such connective structures are particularly useful for standard electronic configurations, such as that employed for Surface Mounted Devices or for applications such as printed electronics or nanoembossed electronic elements.

Turning finally to FIGS. 8a and 8b there are illustrated various metal elements provided at different levels within a thermoplastic bulk body 64. That is, from the perspective front view of FIG. 8a. and the side view of FIG. 8b, it will be appreciated that both elements 66, 68 are provided at an upper level within the bulk body 64, whereas the element 70 is provided a lower level.

It should therefore be appreciated that the present invention can provide for a method of forming a relief pattern as part of a layered structure and comprising, forming a relief pattern on the surface of a layer of the said structure and subsequently forming a protective fixing layer on at least part of the said relief pattern and serving to protect the underlying relief pattern during any subsequent processing of the said structure, and thereby also provides for a layered structure, generally comprising a substrate having a relief pattern formed on a surface of the substrate and wherein at least a portion of the said relief has been provided with a protective fixing layer serving to retain the characteristics of the relief pattern during any subsequent processing of the structure such as, for example, when forming a laminate structure with the relief pattern provided therein.

It will of course be appreciated that the invention is not restricted to the details of the foregoing embodiments insofar as any appropriate material can be employed to fix the

relief structure of the substrate and, in some instances, the metallised elements do not include any particular relief pattern. For such embodiments of the present invention where the layer being “fixed” and whether metallised not, exhibits a relief pattern that is absent then that part of the structure can be considered to comprise a relief pattern of

negligible gradient.

1. A method of forming a relief pattern as part of a layered structure comprising, forming a relief pattern on the surface of a layer of the said structure and subsequently forming a protective fixing layer on at least part of the said relief pattern and serving to protect the underlying relief pattern during any subsequent processing of the said structure.

2. A method as claimed in Claim 1, and including the step of forming a micro-relief pattern.

3. A method as claimed in Claim 1, and including step of forming a diffractive and/or holographic surface relief pattern.

4. A method as claimed in Claim 1, and including forming the relief pattern on a substrate or other appropriate layer of the structure.

5. A method as claimed in claim 1, and including forming the relief pattern on the surface of a thermoplastic material layer.

6. A method as claimed in claim 1, and including forming the relief pattern on the surface of one of an organic or inorganic, material layer and wherein the fixing layer can comprise an organic or inorganic material.

7. A method as claimed claim 1, wherein the subsequent processing step involves the addition of a further layer overlying at least the protective fixing layer.

8. A method as claimed in claim 7, wherein said further layer is formed of the same or different material as the said substrate or said other appropriate layer.

9. A method as claimed in claim 1, and including the provision of a transparent fixing layer and/or transparent said layer of the structure.

10. A method as claimed in claim 1, the provision of a non-transparent fixing layer or non-transparent said layer.

11. A method as claimed in claim 1 and including the provision of a metallised fixing layer and/or metallised said layers.

12. A method as claimed in claim 1 and including the selective location of the set fixing layer.

13. A method as claimed in claim 12 and including step of depositing the fixing layer in the selected location(s).

14. A method as claimed in claim 13 and including step of galvanic position of the fixing layer.

15. A method as claimed in claim 12 and including a removal step so as to achieve the selected location(s) of the fixing layer.

16. A method as claimed in claim 1 and including an over-printing step for the provision of the fixing layer.

17. A method as claimed in claim 1 wherein the said fixing layer is arranged to offer replication of the relief pattern.

18. A method as claimed in claim 1, wherein the said fixing layer is arranged to form an electronic circuit element within the said structure.

19. A method as claimed in claim 1, wherein the said fixing layer is arranged to form a photonic device within the said structure.

20. A method as claimed in claim 1, wherein the said fixing layer forms at least part of one of a surface element, or buried element, of the said structure.

21. A layered structure including a relief pattern on the surface of a layer of the said structure, and a protective fixing layer provided on at least part of the said relief pattern and arranged to protect the underlying relief pattern during any subsequent processing of the said structure.

22. A layered structure as claimed in claim 21, wherein said relief pattern comprises a micro-relief pattern.

23. A layered structure as claimed in claim 21, wherein the relief pattern comprises a diffractive and/or holographic surface relief pattern.

24. A layered structure as claimed in claim 21, wherein the said layer comprises a substrate or other appropriate layer.

25. A layered structure as claimed in claim 21, wherein the said layer comprises a thermoplastic material layer.

26. A layered structure as claimed in claim 21, wherein the said layer and or fixing layer comprises one of an organic, or inorganic, material layer.

27. A layered structure as claimed in claim 21, and including a further layer overlying at least the said protective fixing layer.

28. A layered structure as claimed in claim 27, wherein said further layer is formed of the same or different material as the said substrate.

29. A layered structure as claimed in claim 21, and including a transparent fixing layer and or a transparent said layer.

30. A layered structure as claimed in claim 21, and including a non-transparent fixing layer and/or non-transparent said layer.

31. A layered structure as claimed in claim 21, wherein the said fixing layer comprises a metallised fixing layer.

32. A layered structure as claimed in claim 21, wherein the said fixing layer is selectively located over a region of the said relief pattern.

33. A layered structure as claimed in claim 32 and comprising a deposited fixing layer.

34. A layered structure as claimed in claim 33 and including a galvanically deposited fixing layer.

35. A layered structure as claimed in claim 32, wherein regions of the fixing layer has been removed so as to arrive at a selective location of the fixing layer.

36. A layered structure as claimed in claim 21 and including an over-printed fixing layer.

37. A layered structure as claimed in claim 21 wherein the said fixing layer is arranged to offer replication of the said relief pattern.

38. A layered structure as claimed in claim 21, wherein the said fixing layer is arranged to form an electronic circuit element within the said structure.

39. A layered structure as claimed in claim 21, wherein the said fixing layer is arranged to form a photonic device within the said structure.

40. A layered structure as claimed in claim 21, wherein the said fixing layer forms at least part of one of a surface element, or buried element, of the said structure.

41. A method as claimed in claim 12 wherein the fixing layer comprises discrete fixing layer elements of suitable dimensions and spacing so as to allow a laser write-through procedure in relation to the structure.

42. A method as claimed in claim 1, and including step of providing a relief pattern exhibiting negligible gradient.

43. A layered structure as claimed in claim 32, wherein the fixing layer comprises discrete fixing layer elements having suitable dimensions and spacing as to allow a laser write-through procedure in relation to the said structure.

44. A layered structure as claimed in claim 21, wherein the relief pattern exhibits negligible gradient.
